(19) United States
(12) Patent Application Publication
(10) Pub. No.: US 2009/0206379 A1
(43) Pub. Date: Aug. 20, 2009

(54) SEMICONDUCTOR DEVICE AND MANUFACTURING METHOD THEREOF

(75) Inventors: Soichirou Kitazaki, Yokohama-shi (JP); Hideaki Aochi, Kawasaki-shi (JP); Kyoichi Suguro, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/389,266

(22) Filed: Feb. 19, 2009

(30) Foreign Application Priority Data
Feb. 20, 2008 (JP) 2008-38738

(51) Int. Cl. H01L 25/00; H01L 21/00; H01L 29/66; H01L 21/336

(52) U.S. Cl. 257/295; 438/3; 257/296; 438/109; 438/239; 257/E25.001; 257/E21.001

(57) ABSTRACT

A semiconductor device which can prevent the degradation of contact yield even when subjected to a high-temperature and long-time thermal process, and a manufacturing method thereof are provided. The semiconductor device includes: a first semiconductor circuit formed on a semiconductor substrate; a second semiconductor circuit formed above the first semiconductor circuit; an interlayer insulating film formed between the first semiconductor circuit and the second semiconductor circuit; and a contact plug formed in a state of penetrating the interlayer insulating film, the contact plug including a contact plug body made up of a conductor, and a contact plug coating which is insulating and which covers at least a portion of a side face of the contact plug body in contact with the interlayer insulating film.

### CROSS REFERENCE TO RELATED APPLICATION

This application is based upon and claims the benefit of priority from prior Japanese Patent Application No. 2008-38738, filed on Feb. 20, 2008, the entire contents of which is incorporated herein by reference.

### BACKGROUND OF THE INVENTION

1. Field of the Invention

The present invention relates to a semiconductor device and a manufacturing method thereof, for example, a ferroelectric memory and a manufacturing method thereof.

2. Background Art

In a semiconductor device such as a ferroelectric memory, a ferroelectric capacitor and an element such as a transistor are electrically connected with a contact plug made of a metal material. The surface of the contact plug will have been oxidized by a high-temperature and long-time thermal process in the manufacturing process. Specifically, in the manufacturing of a ferroelectric memory, a deposition of ferroelectric film and so on is performed after a contact layer having a contact plug is formed. At this moment, an oxidizing gas (for example, oxygen and/or water vapor) is generated from an interlayer insulating film due to a high-temperature and long-time thermal process (for example, at 500° C. for not less than 30 minutes). The oxidizing gas diffuses to a contact plug thereby oxidizing the interface between the contact plug and a terminal (a source or drain) of the transistor.

Meanwhile, a barrier metal is conventionally formed at the outer periphery of a contact plug as described above. The barrier metal facilitates embedding a metal material into a contact hole. Moreover, the barrier metal prevents electromigration and diffusion of the metal embedded in the contact plug, as well as diffusion of silicon in a silicon substrate to the contact plug, or the like. However, the diffusion of oxidizing gas generated from the interlayer insulating film mentioned above will not be prevented by the barrier metal.

That is, an oxidizing gas generated from an interlayer insulating film will diffuse to a contact plug. As the result of this, at the interface (hereinafter, referred to as a contact interface) at which the bottom face of the contact plug is in contact with another element (for example, a source/drain diffusion layer of a MOS-FET, another contact plug, or wiring, etc.), metal oxide or silicon oxide (SiO₂) is generated thereby degrading contact yield. In this respect, contact yield means a proportion (yield) of the contact interface where the resistance is within a permitted range.

There is known as a method of preventing the oxidation of such a contact plug, a method of depositing a conductive thin film having oxygen barrier performance on the side face and bottom face of a contact hole, when performing oxygen annealing for making the ferroelectric layer made up of an oxygen containing compound recover from an oxygen deficit (Japanese Patent Laid-Open No. 2006-60107).

However, the technique of the above described document cannot cope with a high-temperature and long-time thermal process. This is because, as the conductive material to be deposited on the entire inner wall (the side face and bottom face) of a contact hole, a conductive material containing metal such as titanium (Ti), chromium (Cr), and so on is used. As the result of this, when exposed to, for example, an oxidizing gas such as moisture contained in an interlayer insulating film, in a high-temperature and long-time thermal process, there is a risk that the conductive material are oxidized thereby degrading contact yield.

### SUMMARY OF THE INVENTION

According to an aspect of the present invention, there is provided a semiconductor device, including:

a first semiconductor circuit formed on a semiconductor substrate;

a second semiconductor circuit formed above the first semiconductor circuit;

an interlayer insulating film formed between the first semiconductor circuit and the second semiconductor circuit; and

a contact plug formed in a state of penetrating the interlayer insulating film, the contact plug including a contact plug body made up of a conductor, and a contact plug coating which is insulating and which covers at least a portion of a side face of the contact plug body in contact with the interlayer insulating film.

According to another aspect, there is provided a manufacturing method of a semiconductor device, including:

forming a first semiconductor circuit on a semiconductor substrate;

forming an interlayer insulating film for covering the first semiconductor circuit;

opening a contact hole penetrating the interlayer insulating film such that a surface of the semiconductor substrate is exposed;

depositing an insulating contact plug coating on a side face of the contact hole and a surface of the semiconductor substrate as a bottom face of the contact hole, the contact plug coating being adapted to prevent oxidizing gas from diffusing;

removing the contact plug coating deposited on the bottom face of the contact hole;

forming a contact plug body by embedding a conductor in the contact hole; and

forming a second semiconductor circuit above the interlayer insulating film.

### BRIEF DESCRIPTION OF THE DRAWINGS

FIG. 1 is a sectional view of a semiconductor device according to a first embodiment;

FIG. 2 is a sectional view of a semiconductor device according to a second embodiment;

FIG. 3 is a sectional view of a semiconductor device according to a third embodiment;

FIG. 4 is a sectional view of a semiconductor device according to a fourth embodiment;

FIG. 5 is a sectional view of a semiconductor device according to a fifth embodiment;

FIG. 6A is a sectional view to show a manufacturing process of a semiconductor device according to the first embodiment;

FIG. 6B is a sectional view, following FIG. 6A, to show a manufacturing process of a semiconductor device according to the first embodiment;

FIG. 6C is a sectional view, following FIG. 6B, to show a manufacturing process of the semiconductor device according to the first embodiment;

FIG. 6D is a sectional view, following FIG. 6C, to show a manufacturing process of the semiconductor device according to the first embodiment;

FIG. 6E is a sectional view, following FIG. 6D, to show a manufacturing process of the semiconductor device according to the first embodiment;

FIG. 6F is a sectional view, following FIG. 6E, to show a manufacturing process of the semiconductor device according to the first embodiment;

FIG. 6G is a sectional view, following FIG. 6F, to show a manufacturing process of the semiconductor device according to the first embodiment;

FIG. 6H is a sectional view, following FIG. 6G, to show a manufacturing process of the semiconductor device according to the first embodiment;

FIG. 6I is a sectional view, following FIG. 6H, to show a manufacturing process of the semiconductor device according to the first embodiment;

FIG. 6J is a sectional view, following FIG. 6I, to show a manufacturing process of the semiconductor device according to the first embodiment;

FIG. 6K is a sectional view, following FIG. 6J, to show a manufacturing process of the semiconductor device according to the first embodiment;

FIG. 6L is a sectional view, following FIG. 6K, to show a manufacturing process of the semiconductor device according to the first embodiment;

FIG. 6M is a sectional view, following FIG. 6L, to show a manufacturing process of the semiconductor device according to the first embodiment;

FIG. 6N is a sectional view, following FIG. 6M, to show a manufacturing process of the semiconductor device according to the first embodiment;

FIG. 6O is a sectional view, following FIG. 6N, to show a manufacturing process of the semiconductor device according to the first embodiment;

FIG. 6P is a sectional view, following FIG. 6O, to show a manufacturing process of the semiconductor device according to the first embodiment;

FIG. 6Q is a sectional view, following FIG. 6P, to show a manufacturing process of the semiconductor device according to the first embodiment;

FIG. 6R is a sectional view, following FIG. 6Q, to show a manufacturing process of the semiconductor device according to the first embodiment;

FIG. 7 shows a hysteresis characteristic of a ferroelectric memory with and without a high-temperature interlayer insulating film;

FIG. 8 shows a measurement result of contact resistance after being subjected to a thermal process in the case without an insulating oxidizing-gas-diffusion prevention film;

FIG. 9A shows a measurement result of contact resistance after being subjected to a thermal process in the case with an insulating oxidizing-gas-diffusion prevention film having a film thickness of 10 nm;

FIG. 9B shows a measurement result of contact resistance after being subjected to a thermal process in the case with an insulating oxidizing-gas-diffusion prevention film having a film thickness of 15 nm; and

FIG. 9C shows a measurement result of contact resistance after being subjected to a thermal process in the case with an insulating oxidizing-gas-diffusion prevention film having a film thickness of 20 nm.

### DESCRIPTION OF THE EMBODIMENTS

Hereinafter, first to fifth embodiments according to the present invention will be described in detail with reference to the drawings. It is noted that through all the drawings, like components are given like reference characters unless otherwise stated. All numerical values are exemplary.

A first embodiment relates to a semiconductor device in which an insulating film (hereinafter, referred to as an insulating oxidizing-gas-diffusion prevention film) for preventing the diffusion of oxidizing gas is formed only on a side face of a contact hole as a contact plug coating so that contact yield is not degraded even after being subjected to a high-temperature and long-time thermal process, and a manufacturing method thereof.

A second embodiment relates to a semiconductor device in which contact yield is not degraded even after being subjected to a high-temperature and long-time terminal process as with the first embodiment, and a manufacturing method thereof, and the second embodiment differs from the first embodiment in that an insulating oxidizing-gas-diffusion prevention film is formed only on a portion of interlayer insulating film of the side face of a contact hole.

A third embodiment relates to a semiconductor device which includes a contact plug according to the first or second embodiment and further includes a ferroelectric capacitor formed on an interlayer insulating film which is formed at a high temperature and a manufacturing method thereof.

A fourth embodiment differs from the first embodiment in that it has one or more interlayer insulating films between an insulating film on which a transistor is created and an insulating film on which a ferroelectric capacitor is created.

A fifth embodiment relates to a semiconductor device in which a contact plug including an insulating oxidizing-gas-diffusion prevention film is formed in an interlayer insulating film of a Low-k film.

### First Embodiment

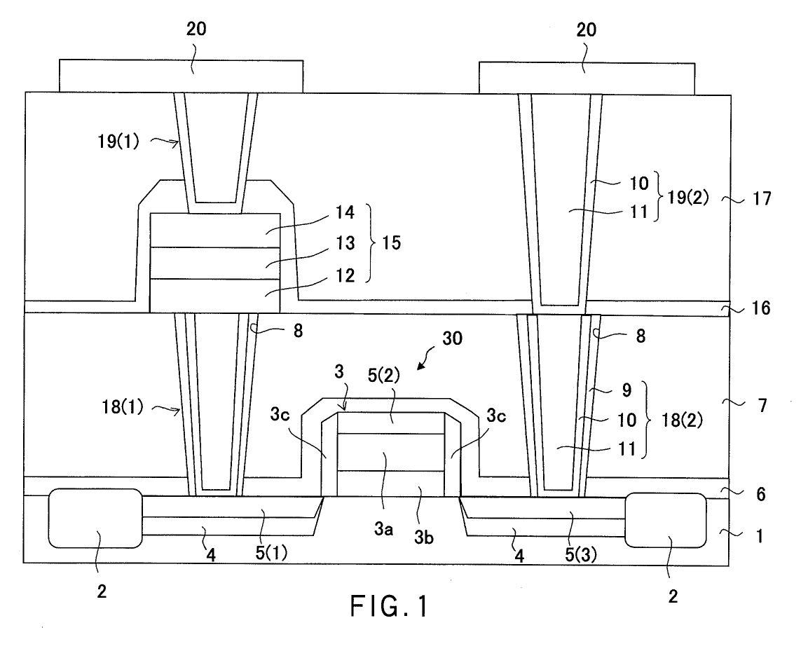

FIG. 1 shows a sectional view of a semiconductor device according to a first embodiment. This semiconductor device functions as a ferroelectric memory (FeRAM). This semiconductor device has a configuration in which a ferroelectric capacitor 15, first contact plug 18(1), a transistor 30, and first contact plug 18(2) are electrically connected in series. A contact layer 5(2) and a gate electrode 3a make up a part of a word line (not shown) which is to be formed in a perpendicular direction to the plane of the figure. A wiring pattern 20 is electrically connected with a bit line and a plate line (not shown), etc.

As seen from FIG. 1, the ferroelectric capacitor 15 includes a lower electrode 12, a ferroelectric film 13 and an upper electrode 14. The transistor 30 includes a gate 3, source/drain diffusion layers 4, and 4, and contact layers 5(1), 5(2), and 5(3). In this configuration, the gate 3 includes a gate electrode 3a, a gate oxide film 3b, and a sidewall insulating film 3c. As seen from FIG. 1, the surfaces of the gate electrode 3a and the source/drain diffusion layers 4, 4 are silicidated to form the above described contact layers 5(1), 5(2), and 5(3). These contact layers 5(1), 5(2), and 5(3) are for decreasing the contact resistance with a contact plug etc. and a metal silicide (for example, CoSi, NiSi, TiSi, and WSi) is used therefor.

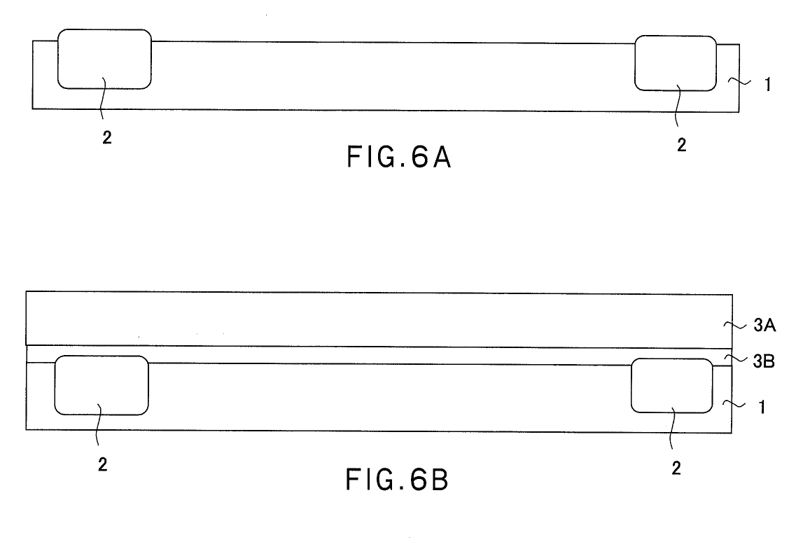

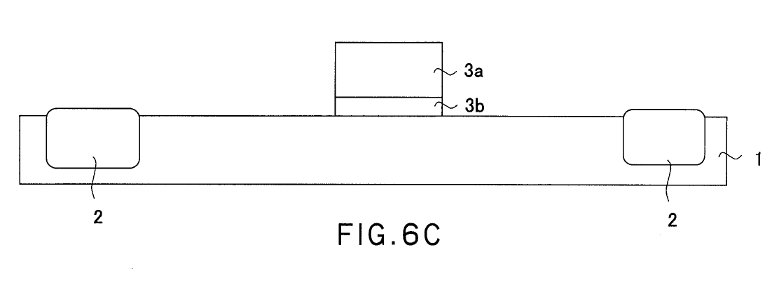

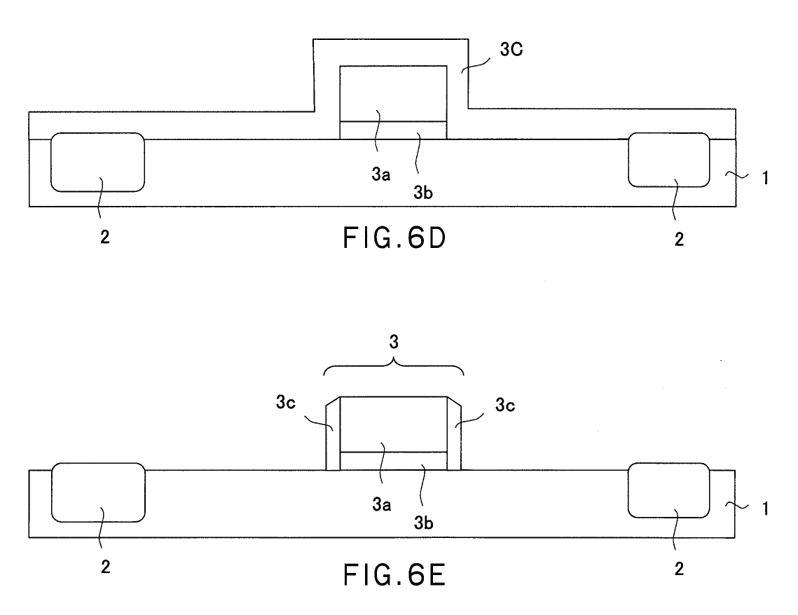

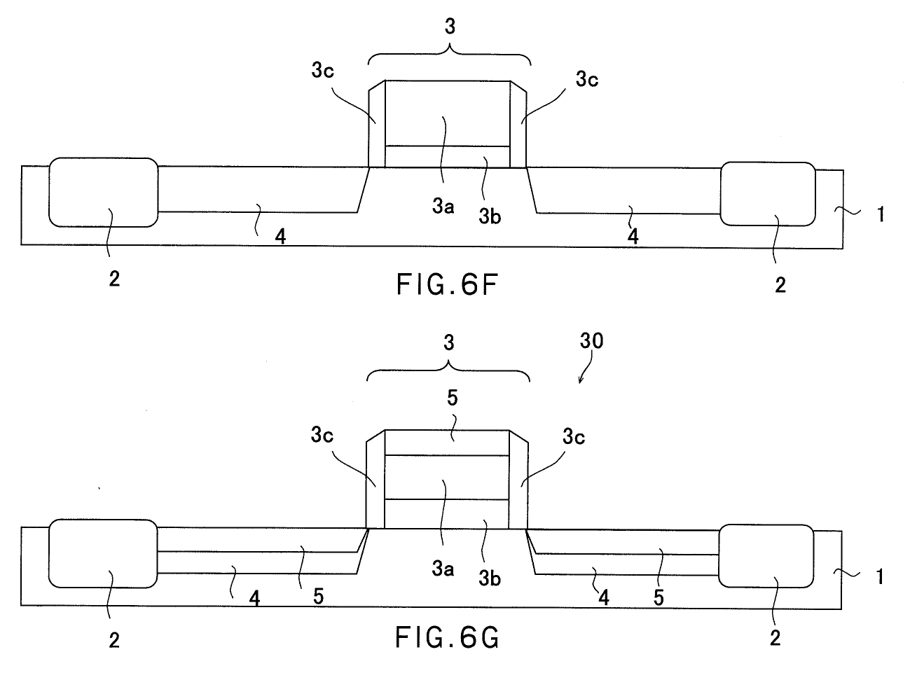

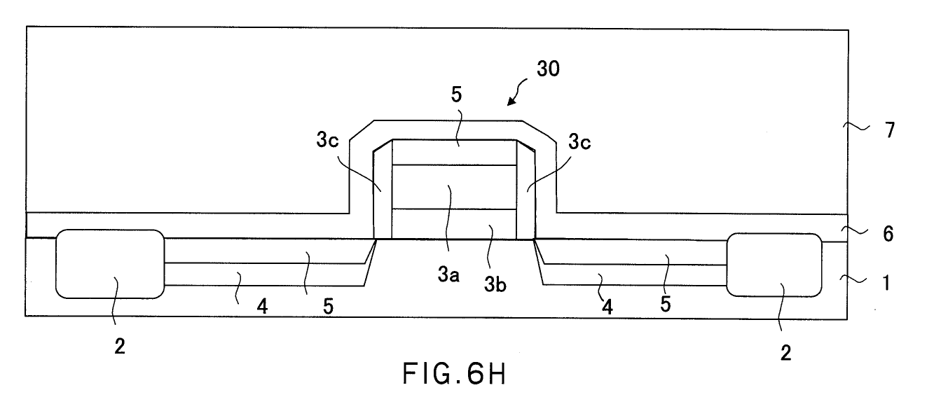

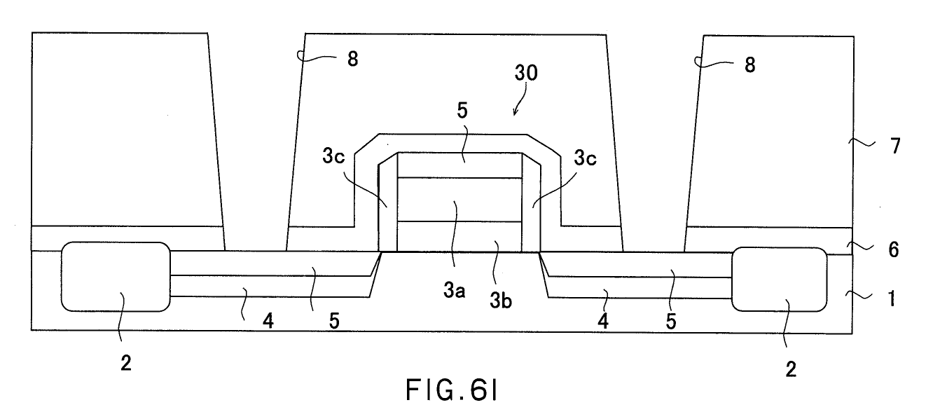

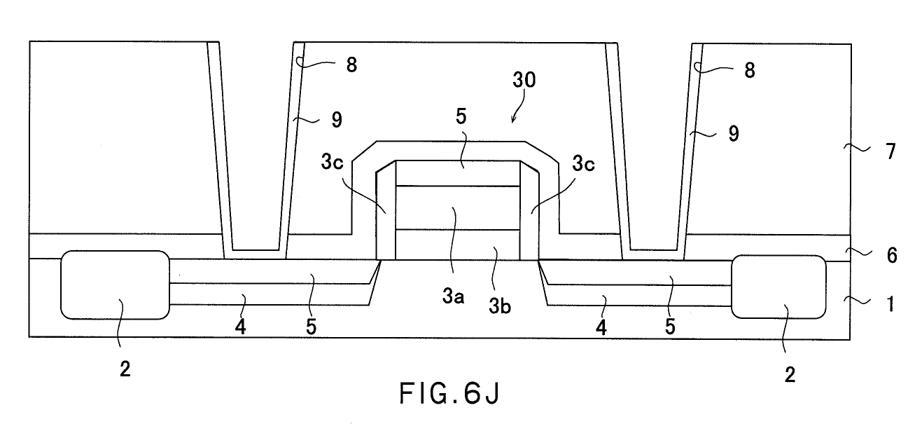

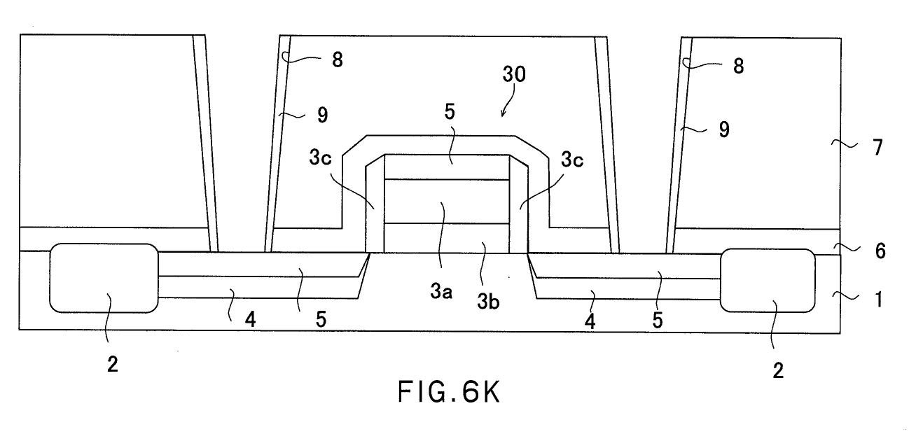

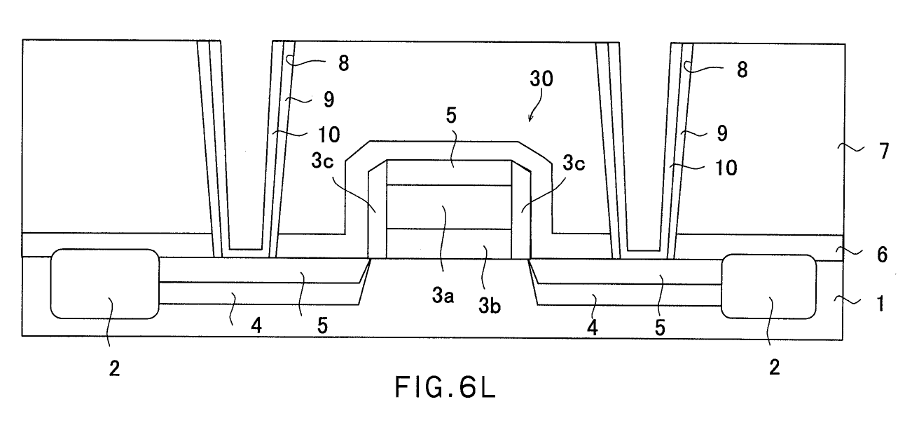

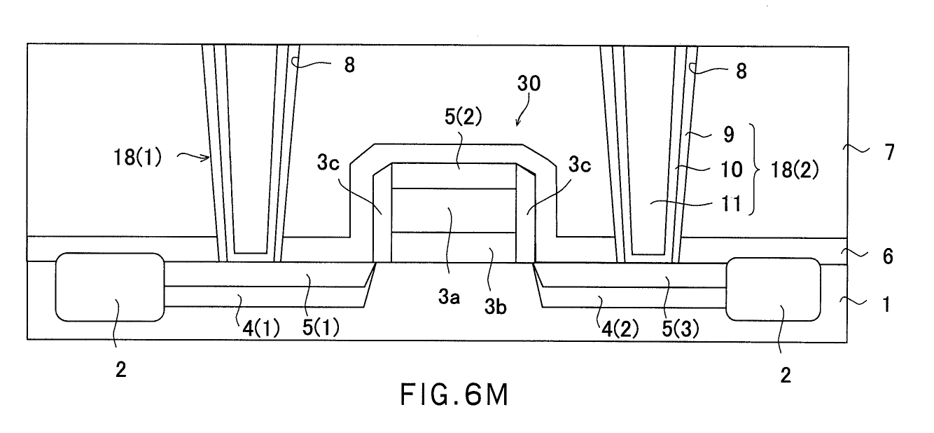

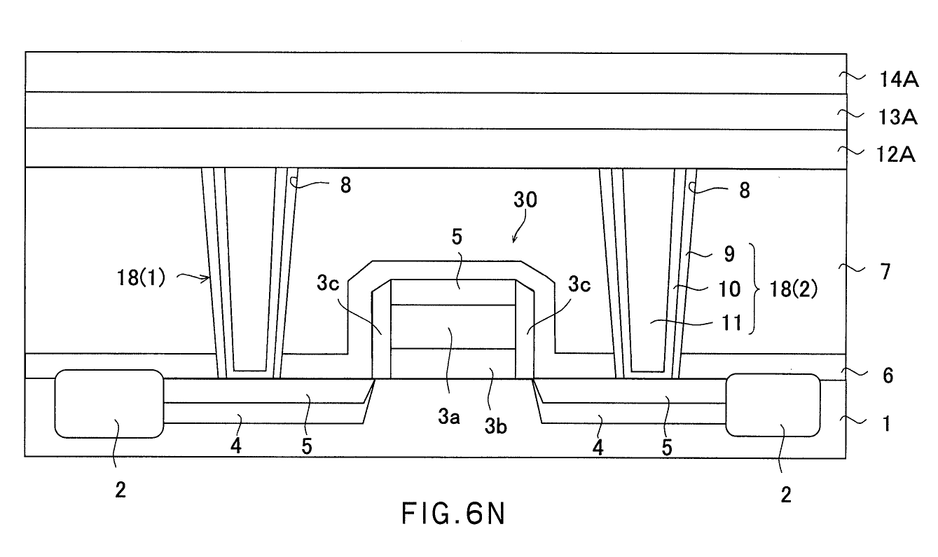

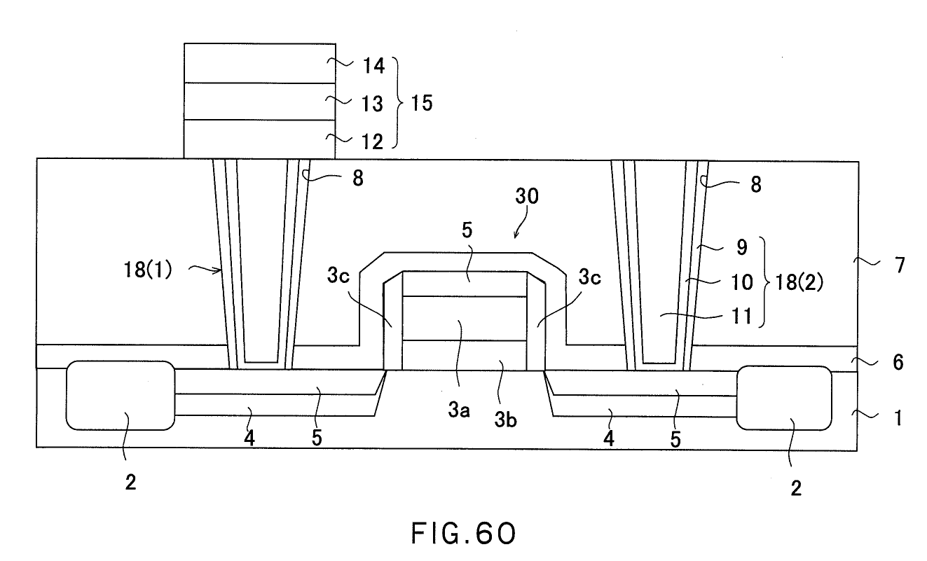

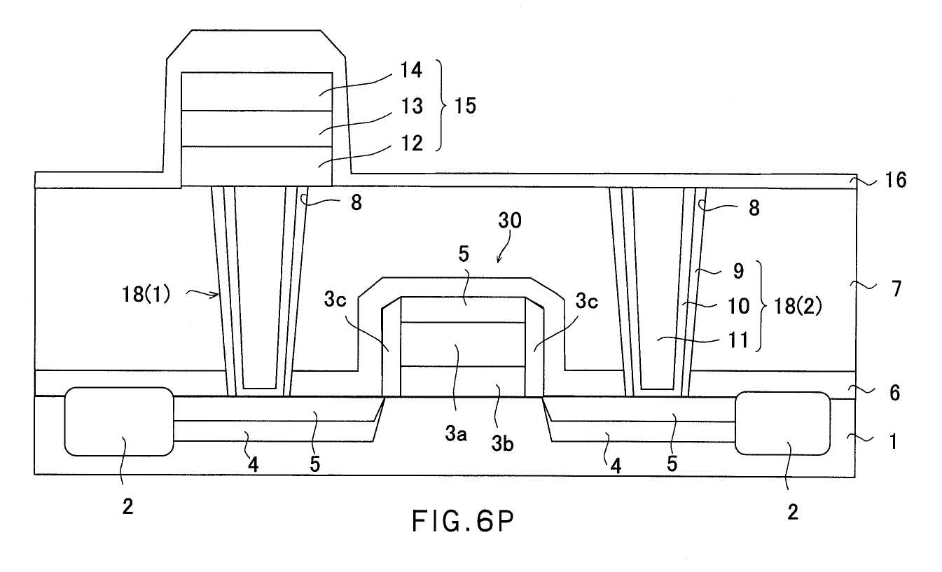

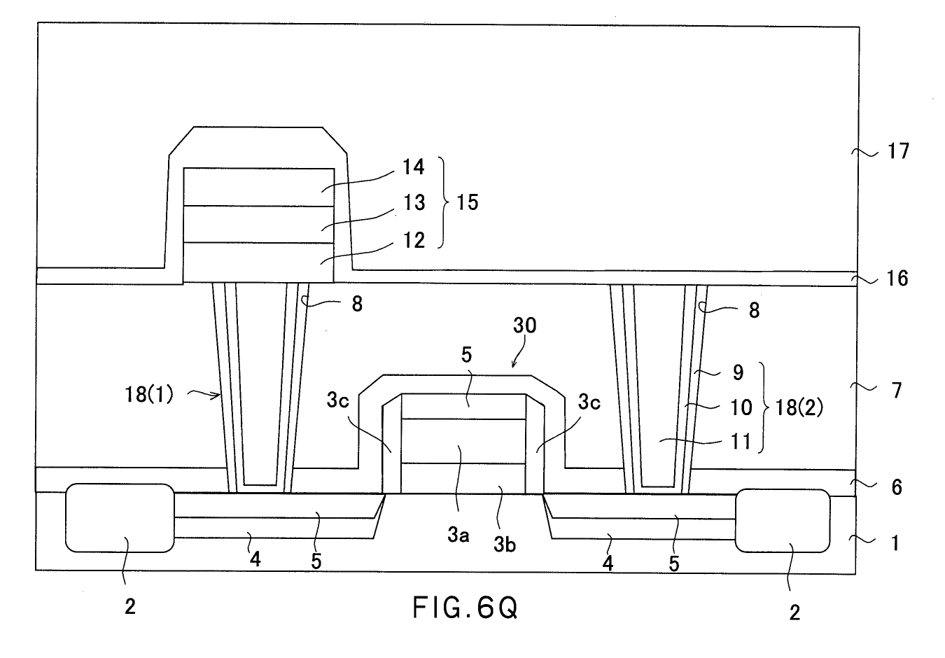

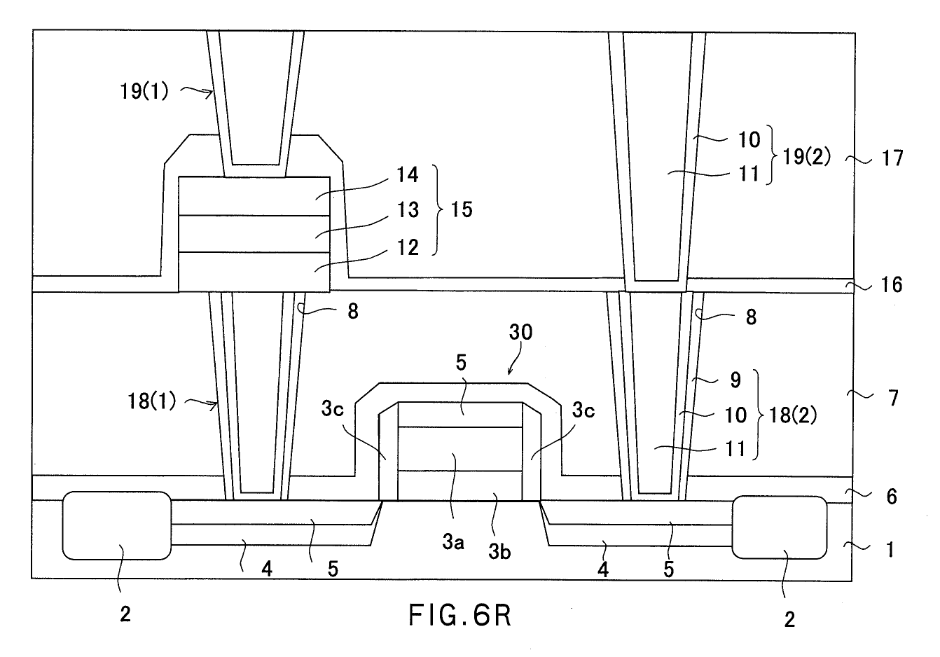

Next, a manufacturing method of the semiconductor device according to the present embodiment will be described using FIGS. 6A to 6R and FIG. 1.
(1) First, as shown in FIG. 6A, an element-isolation insulating film 2 for performing element isolation in a silicon substrate 1 is formed by STI (Shallow Trench Isolation) technology.
(2) Next, as shown in FIG. 6B, an oxide film 3B for forming a gate oxide film is deposited on the silicon substrate 1 and the element-isolation insulating film 2. The oxide film 3B is, for example, a silicon oxide film (SiO₂). Then, polysilicon 3A for forming a gate electrode is deposited on the oxide film 3B.
(3) Next, as shown in FIG. 6C, the polysilicon 3A and the oxide film 3B are removed by etching leaving only part of them to form a gate electrode 3a and a gate oxide film 3b.
(4) Next, as shown in FIG. 6D, an insulating film 3C for forming a sidewall insulating film is deposited in such a way to cover the silicon substrate 1, the gate electrode 3a, and gate oxide film 3b. The insulating film 3C is, for example, a silicon nitride (SiN) film.
(5) Next, as shown in FIG. 6E, the insulating film 3C is etched leaving only the portions on the side faces of the gate electrode 3a and the gate oxide film 3b and removing the remaining portion to form a sidewall insulating film 3c. As the result of this, a gate 3 including the gate electrode 3a, the gate oxide film 3b, and the sidewall insulating film 3c is formed.
(6) Next, as shown in FIG. 6F, a source/drain diffusion layer 4, 4 is formed on each side of the gate 3.
(7) Next, as shown in FIG. 6G, the surfaces of the gate electrode 3a and the source/drain diffusion layer 4, 4 are silicidated to form a contact layer 5. The contact layer 5 is formed by depositing and thereafter annealing metal (for example, Co, Ti, and Ni) on the gate electrode 3a and the source/drain diffusion layer 4, 4. As the result of this, a transistor 30 including the gate 3, the source/drain diffusion layer 4, 4, and the contact layer 5 is formed.
(8) Next, as shown in FIG. 6H, a barrier film 6 is deposited in a thickness of 20 to 30 nm in such a way to cover the silicon substrate 1, the element-isolation insulating film 2, and the transistor 30. The barrier film 6 is for preventing intrusion of moisture into the silicon substrate 1 and the transistor 30 and, for example, SiN is used as the material therefor.
(9) Next, as. seen from FIG. 6H, a first interlayer insulating film 7 is deposited in a thickness of 100 nm to 500 nm on the barrier film 6 and is thereafter planarized by means of CMP The material for the first interlayer insulating film 7 includes, for example, BPSG (Boron Phosphorous Silicate Glass), NSG (Non-Doped Silicate Glass), and P-TEOS (Plasma Tetra Ethoxy Silane). It may be a Low-k film such as FSG (Fluoride Silicate Glass). It may also be an organic coated film (SiC, SiOC, SiOF, and so on).
(10) Next, as shown in FIG. 6I, the first interlayer insulating film 7 and the barrier film 6 lying thereunder are selectively removed by use of, for example, RIE (Reactive Ion Etching) with a resist patterned by photolithography as a mask to form a first contact hole 8. As seen from FIG. 6I, the contact layer 5 of the region of the source/drain diffusion layer 4 is exposed in the bottom of the first contact hole 8. It is noted that the first contact hole 8 has a diameter of 0.1 μm to 0.3 μm.
(11) Next, as shown in FIG. 6J, an insulating oxidizing-gas-diffusion prevention film 9 is deposited on the side face of the first contact hole 8 and the contact layer 5 as the bottom face of the first contact hole 8 by using, for example, a CVD method, a sputtering method, or an ALD (Atomic Layer Deposition) method. The insulating oxidizing-gas-diffusion prevention film 9 has a thickness of 5 nm to 50 nm, preferably 5 nm to 30 nm.

The insulating oxidizing-gas-diffusion prevention film 9 has a capability of insulating and preventing oxidizing-gas diffusion. Examples of the material for the insulating oxidizing-gas-diffusion prevention film 9 include silicon nitride (SiN), aluminum oxide (Al₂O₃), and others.
(12) Next, as shown in FIG. 6K, the insulating oxidizing-gas-diffusion prevention film 9 deposited on the bottom face of the first contact hole 8 is removed by using for example a RIE method. As the result of this, as seen from FIG. 6K, the insulating oxidizing-gas-diffusion prevention film 9 is deposited only on the side face of the first contact hole 8.
(13) Next, as shown in FIG. 6L, a barrier metal 10 is deposited on the insulating oxidizing-gas-diffusion prevention film 9 and the contact layer 5. The barrier metal 10 is made up of TiN, Ti, TaN or Ta, etc., or a combination of two or more layers thereof.
(14) Next, as shown in FIG. 6M, a metal material 11 is embedded into the first contact hole 8. Thereafter, the upper surface of the first interlayer insulating film 7 is planarized by means of CMP to form first contact plugs 18. As seen from FIG. 6M, the first contact plugs 18 are configured such that the insulating oxidizing-gas-diffusion prevention film 9 covers the side face of the contact plug body having the barrier metal 10 and the metal material 11. Examples of the metal material 11 include tungsten (W), aluminum (Al), and others.

It is noted that, as seen from FIG. 6M, the first contact plugs 18(1) and 18(2) are electrically connected respectively with the contact layers 5(1) and 5(3).
(15) Next, as shown in FIG. 6N, a lower electrode material 12A, a ferroelectric material 13A, and an upper electrode material 14A are successively deposited on the interlayer insulating film 7 and the first contact plugs 18. In this configuration, the lower electrode material 12A and the upper electrode material 14A include at least one kind selected from the group consisting of, for example, Pt, Ir, IrO₂, SRO (SrRuO₃), Ru, and RuO₂. Moreover, the ferroelectric material 13A includes any of, for example, PZT (lead zirconate titanate), SBT (strontium bismuth tantalate), and the like.
(16) Next, as shown in FIG. 6O, the lower electrode material 12A, the ferroelectric material 13A, and the upper electrode material 14A are etched by, for example, RIE such that only part of them will be left, to form a ferroelectric capacitor 15. The ferroelectric capacitor 15 has a lower electrode 12, a ferroelectric film 13, and an upper electrode 14.

It is noted that as seen from FIG. 6O, the lower electrode 12 is electrically connected with first contact plug 18(1).
(17) Next, as shown in FIG. 6P, a hydrogen barrier film 16 is deposited so as to cover the ferroelectric capacitor 15 and the first interlayer insulating film 7. The hydrogen barrier film 16 is for preventing hydrogen from intruding into the ferroelectric capacitor 15 thereby deteriorating the polarization characteristic of the ferroelectric. For example, alumina is used for the material of the hydrogen barrier film 16.
(18) Next, as shown in FIG. 6Q, a second interlayer insulating film 17 is deposited on the hydrogen barrier film 16 and is thereafter planarized by CMP.

It is noted that the same material as that of the first interlayer insulating film 7 can be used as the second interlayer insulating film. (19) Next, as shown in FIG. 6R, the second interlayer insulating film 17 and the hydrogen barrier film 16 are selectively removed by, for example, RIE with a resist patterned by photolithography as a mask to open a contact hole. Then, after a barrier metal 10 is deposited on the side face and the bottom face of the contact hole, a metal material 11 is embedded into the contact hole. As the result of this, contact plugs 19(1) and 19(2) are created. The contact plugs 19(1) and 19(2) are a contact plug of a conventional structure including no insulating oxidizing-gas-diffusion prevention film 9. The reason why such a conventional structure is adopted is because there is no later thermal process which may cause the oxidation of the contact plug.

It is noted that, as seen from FIG. 6R, the contact plug 19(1) is electrically connected with the ferroelectric capacitor 15, and the contact plug 19(2) with first contact plug 18(2), respectively.
(20) Next, as seen from FIG. 1, a material for forming wiring, for example, aluminum (Al) is deposited on the second interlayer insulating film 17. Thereafter, a wiring pattern 20 is formed through the processing by, for example, RIE with a resist patterned by photolithography as a mask.

It is noted that, as shown in FIG. 1, the wiring pattern 20 is electrically connected with conventional contact plugs 19(1) and 19(2).

The semiconductor device according to the present invention is manufactured by the above described manufacturing method.

Next, a thermal process when depositing a ferroelectric material 13A and the effect thereof will be described in further detail.

The method of depositing the ferroelectric material 13A is a MOCVD method or a sputtering method, etc. When a MOCVD method is used, it is necessary to form a film of the ferroelectric material 13A under a condition at 500° C. for not less than 30 minutes in order to obtain a good ferroelectric characteristic.

When a sputtering method is used, crystallization annealing will become necessary after sputtering in order to obtain a good ferroelectric characteristic. The condition of the crystallization annealing is at 600° C. for not less than 10 minutes when PTZ is used as the ferroelectric material 13A, and at 700° C. for not less than 10 minutes when SBT is used.

In conventional arts, imposing such a high-temperature and long-time thermal load as described above will cause the oxidizing gas contained in the first interlayer insulating film 7 to diffuse to the first contact-plugs 18, thereby causing the contact interface, that is an interface between the bottom face of the first contact plugs 18 and the contact layer 5, to be oxidized.

However, the insulating oxidizing-gas-diffusion prevention film 9 which is deposited only on the side face of the first contact hole 8 is an insulating film as described above, and it has a capability of preventing the diffusion of oxidizing gas. Therefore, even when a high-temperature and long-time thermal load is imposed, the oxidation of the contact interface due to the oxidizing gas generated from the interlayer insulating film will be prevented. Thus, it becomes possible to avoid degradation of contact yield.

As so far described, according to the present embodiment, a contact plug (the first contact plugs 18) is formed in which the side face of the contact plug body (the barrier metal 10 and the metal material 11) is covered with an insulating contact plug coating (the insulating oxidizing-gas-diffusion prevention film 9). This makes it possible to prevent the diffusion of oxidizing gas generated from the interlayer insulating film to the contact plug body during thermal loading, and thereby avoid the degradation of contact yield. Further, forming such a contact plug in the first interlayer insulating film 7 located below the ferroelectric capacitor makes it possible to impose a high-temperature and long-time thermal load when depositing the ferroelectric material 13A. As the result of this, according to the present embodiment, it is possible to manufacture a ferroelectric memory having a good ferroelectric characteristic at a high yield.

### Second Embodiment

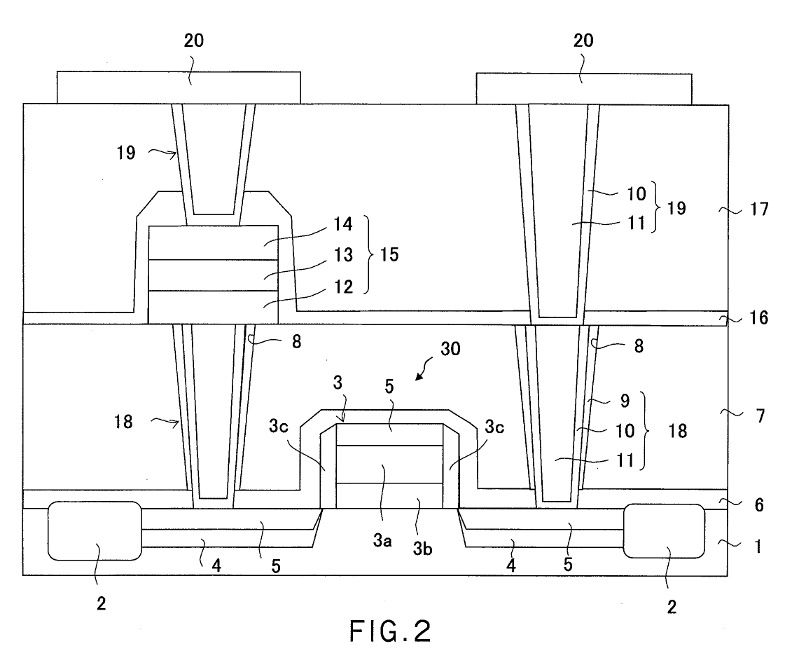

FIG. 2 shows a sectional view of the semiconductor device according to a second embodiment. One point of difference between the present embodiment and the first embodiment is in the structure around the bottom part of the first contact plugs 18 as described above. That is, in the first embodiment, the insulating oxidizing-gas-diffusion prevention film 9 is formed not only on the first interlayer insulating film 7 but also on the portion of the barrier film 6 out of the side face of the first contact hole 8. In contrast, in the present embodiment, as seen from FIG. 2, it is formed only on the portion of the first interlayer insulating film 7.

This is because the manufacturing method of the first contact plugs 18 is different. More specifically, in the present embodiment, the first interlayer insulating film 7 is selectively removed by using, for example, RIE with a resist patterned by photolithography as a mask.

Thereafter, the insulating oxidizing-gas-diffusion prevention film 9 is deposited in a state in which the barrier film 6 of the bottom part of the first contact hole 8 has not been removed.

Thereafter, the insulating oxidizing-gas-diffusion prevention film 9 and the barrier film 6 which are located in the bottom part of the first contact hole 8 are removed by one operation. At this moment, when the insulating oxidizing-gas-diffusion prevention film 9 and the barrier film 6 are of the same material (for example, SiN), concurrent processing is possible by using the same etching gas.

Hereinafter, as with the first embodiment, the barrier metal 10 and the metal material 11 are embedded into the first contact hole 8 to form first contact plugs 18.

According to the present embodiment, as it is obvious from the above described process, the removing process of the insulating oxidizing-gas-diffusion prevention film 9 and the barrier film 6 can be performed concurrently or successively and thus there is an advantage that the processing is simplified.

### Third Embodiment

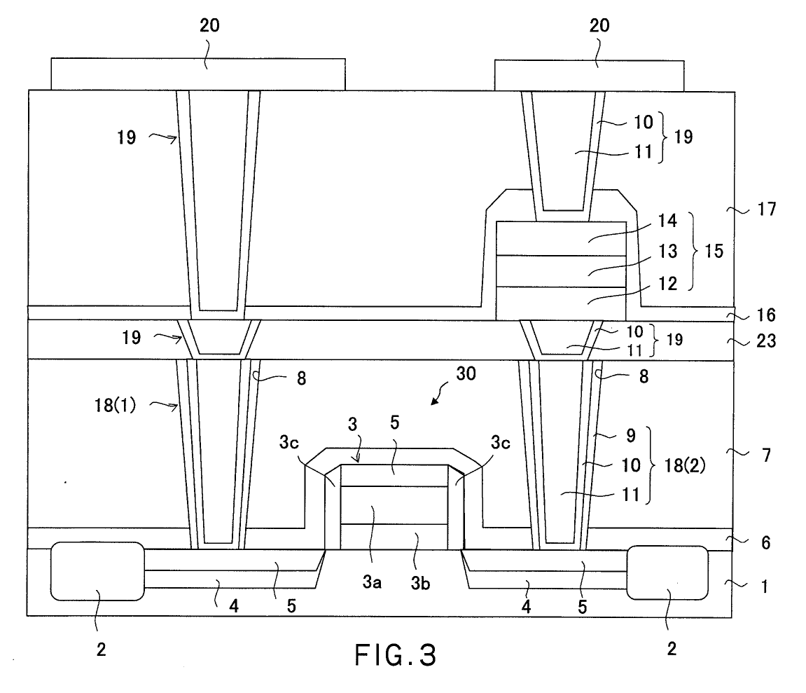

Next, a third embodiment will be described. FIG. 3 shows a sectional view of a semiconductor device according to the third embodiment.

One point of difference between the present embodiment and the first embodiment is that as seen from FIG. 3, a high-temperature interlayer insulating film 23 is deposited between the first interlayer insulating film 7 and the hydrogen barrier film 16. The high-temperature interlayer insulating film 23 is formed into a film under a condition at 600° C. for not less than 1 hour. The high-temperature interlayer insulating film 23 is LP-TEOS (Low Pressure TEOS) or LP-SiN (Low Pressure SiN) which is formed into a film by using a LP-CVD method. The high-temperature interlayer insulating film 23 has a thickness of 200 to 400 nm.

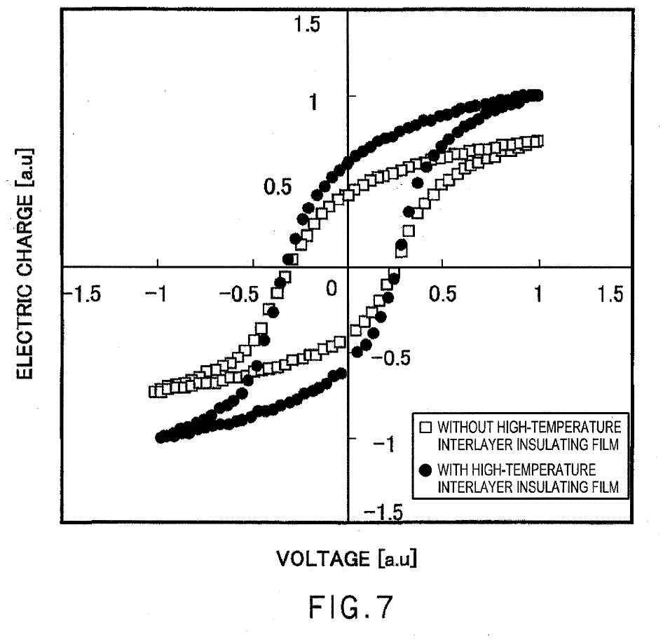

It is possible to obtain a film denser than a usual insulating film by subjecting it to a high-temperature and long-time thermal process. This will improve an orientation property of the lower electrode 12 of the ferroelectric capacitor 15 formed on the high-temperature interlayer insulating film 23. As the result of an orientation property of the ferroelectric film 13 being improved in conjunction with the improvement of the orientation property of the lower electrode 12, there is an improvement in hysteresis characteristic. This will be further described with reference to FIG. 7. FIG. 7 shows measurements of hysteresis characteristic on a ferroelectric memory respectively for the cases with the above described high-temperature interlayer insulating film 23 (a semiconductor device according to the present embodiment) and without the high-temperature interlayer insulating film 23 (a semiconductor device according to the first embodiment). As seen from FIG. 7, the semiconductor device with the high-temperature interlayer insulating film 23 obviously has a larger electric charge under no applied voltage (residual charge). This indicates that a data retention characteristic of the ferroelectric memory has been improved.

Thus, according to the present embodiment, by depositing the high-temperature interlayer insulating film 23 between the first interlayer insulating film 7 and the hydrogen barrier film 16 and forming the ferroelectric capacitor 15 on the high-temperature interlayer insulating film 23, it is possible to obtain a still better ferroelectric characteristic (hysteresis). This is essential for improving the performance of the ferroelectric memory.

It is noted that as the first contact plugs 18, the contact plug described in the second embodiment, that is, a contact plug in which the insulating oxidizing-gas-diffusion prevention film 9 is formed only on the portion of the first interlayer insulating film 7 of the side face of the first contact hole 8 may be used.

Moreover, although the contact plug formed in the high-temperature interlayer insulating film 23 is shown with the contact plug 19 of a conventional structure in FIG. 3, it may be the first contact plugs 18 having the insulating oxidizing-gas-diffusion prevention film 9 according to the first or second embodiment.

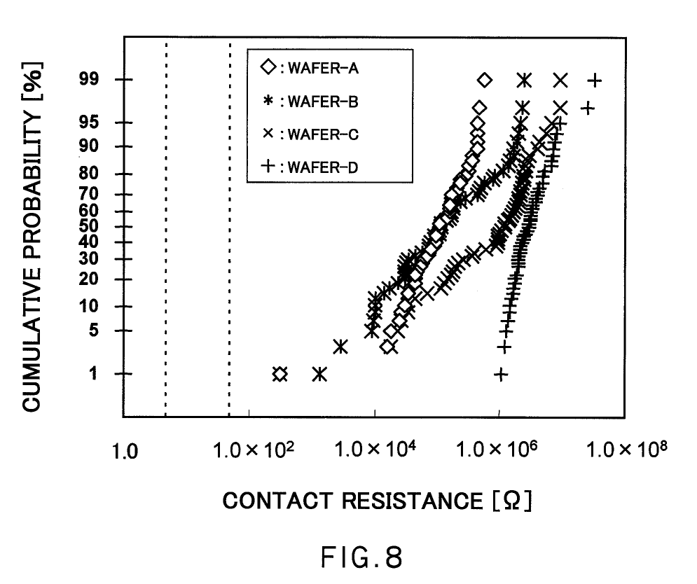

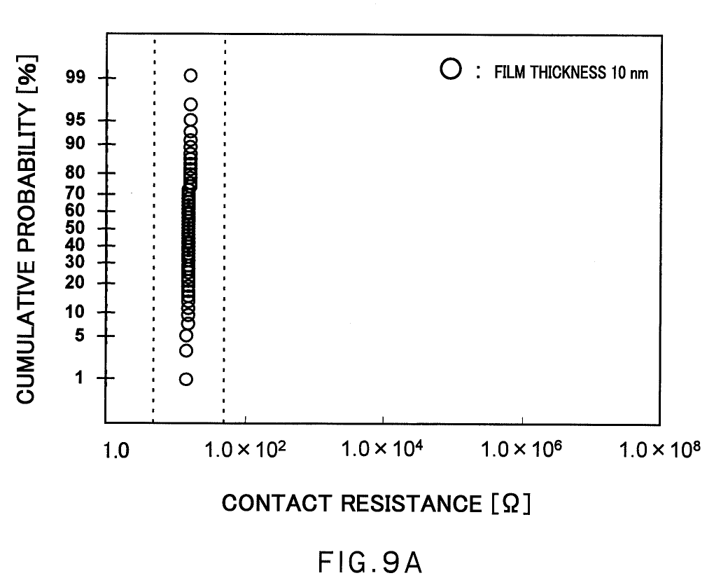

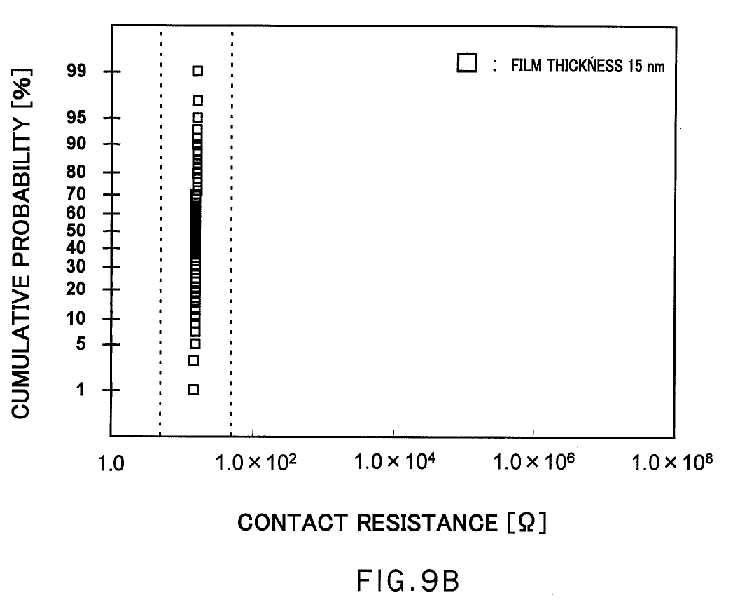

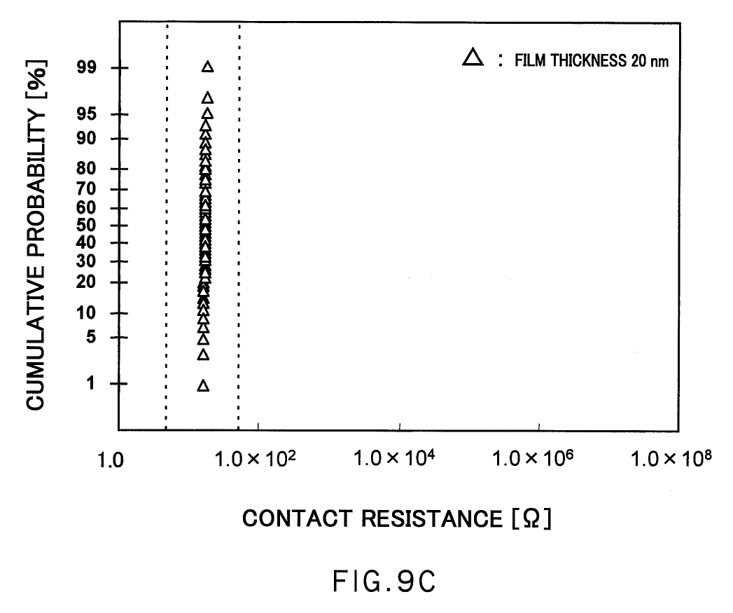

On the other hand, in the present embodiment as well, as with the first contact plugs in the first embodiment, the insulating oxidizing-gas-diffusion prevention film 9 is deposited only on the side face of the first contact hole 8. By doing so, it becomes possible to prevent the oxidation of the contact interface due to the thermal process when forming the high-temperature interlayer insulating film 23 and the ferroelectric material 13A, and to avoid degradation of contact yield. This will be described using FIGS. 8, 9A, 9B and 9C. These figures show a cumulative probability of contact resistance values. They are based on the result of the measurements of the contact resistance between the first contact plugs 18 and the contact layer 5 of the transistor 30 by a four-terminal method on each of the plurality of semiconductor devices (chips) included in one wafer, after being subjected to a high-temperature and long-time thermal process (600° C. for 1 hour). Two dotted lines in the figures show the upper and lower limits of the permissible range of the contact resistance. When the contact resistance is within the permissible range, it is determined to be normal.

FIG. 8 shows the cumulative probability of the contact resistance value respectively for four wafers A, B, C, and D including chips in which no insulating oxidizing-gas-diffusion prevention film 9 is provided in the first contact plugs 18. As seen from the figure, every wafer exhibits a contact resistance exceeding the upper limit, and even a cumulative probability of 1% has not been achieved.

On the other hand, FIGS. 9A to 9C show the cumulative probability of contact resistance value on wafers having a chip in which the insulating oxidizing-gas-diffusion prevention film 9 is provided on the first contact plugs 18. The insulating oxidizing-gas-diffusion prevention film 9 has a thickness of 10 nm, 15 nm, and 20 nm for FIGS. 9A, 9B, and 9C, respectively. As seen from these figures, variation of the contact resistance value is small for any wafer, and the cumulative probability at which a normal contact resistance value is obtained has reached 99%. Thus, it is seen that by providing the insulating oxidizing-gas-diffusion prevention film 9 on the side face of the contact plug, a stable contact resistance within the permissible range is obtained.

As so far described, according to the present embodiment, a ferroelectric memory which combines a good ferroelectric characteristic and a high contact yield can be obtained.

### Fourth Embodiment

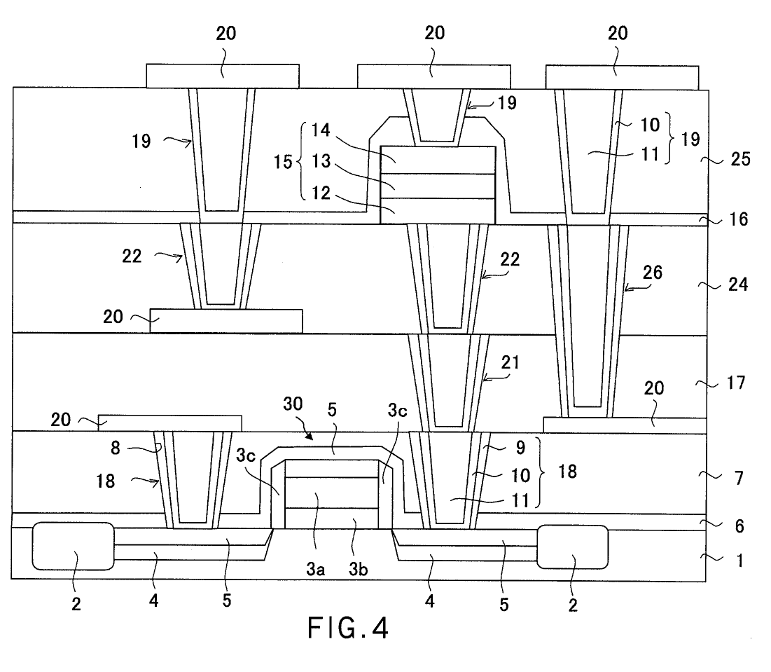

Next, a fourth embodiment will be described. FIG. 4 shows a sectional view of the semiconductor device according to the fourth embodiment.

One point of difference between the present embodiment and the first embodiment is that as seen from FIG. 4, a second interlayer insulating film 17 and a third interlayer insulating film 24 are provided between the first interlayer insulating film 7 and a fourth interlayer insulating film 25 in which a ferroelectric capacitor is created. The contact plugs (a second contact plug 21, a third contact plug 22, and a fourth contact plug 26) formed in the second interlayer insulating film 17 and the third interlayer insulating film 24 are provided with the insulating oxidizing-gas-diffusion prevention film 9 only on the side faces thereof as with the first contact plugs 18 which is described in the first and second embodiments.

Moreover, as seen from FIG. 4, the ferroelectric capacitor 15 is provided in the fourth interlayer insulating film 25. The first contact plugs 18, the second contact plug 21, and the third contact plug 22 are formed respectively in the first interlayer insulating film 7, the second interlayer insulating film 17, and the third interlayer insulating film 24. As seen from FIG. 4, the fourth contact plug 26 is formed so as to penetrate the second interlayer insulating film 17 and the third interlayer insulating film 24.

As described above, the first, second, third, and fourth contact plugs 18, 21, 22, and 26 are deposited with the insulating oxidizing-gas-diffusion prevention film 9 only on the side faces thereof. On the other hand, a contact plug 19 of a conventional structure is formed in the fourth interlayer insulating film 25. The reason why a conventional structure is adopted is because there is no later thermal process which may cause the oxidation of the contact plug.

In other words, there is formed in an interlayer insulating film (the first interlayer insulating film 7, the second interlayer insulating film 17, the third interlayer insulating film 24) which is located below the interlayer insulating film (the fourth interlayer insulating film 25) in which the ferroelectric capacitor 15 is disposed, a contact plug in which the insulating oxidizing-gas-diffusion prevention film 9 is provided only on the side face since it is necessary to cope with the thermal process during the formation of a ferroelectric film.

This makes it possible to prevent the oxidation of the contact interface of the contact plug formed in each interlayer insulating film even when subjected to the thermal process during the deposition of the ferroelectric material 13A, thus avoiding the degradation of contact yield.

### Fifth Embodiment

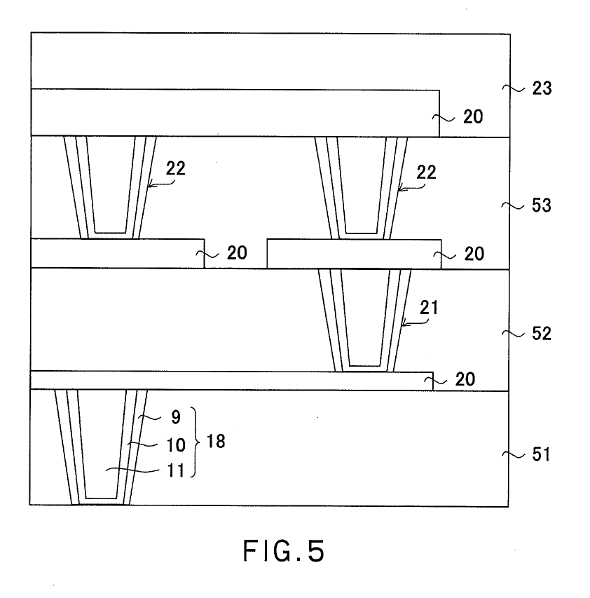

Next, a fifth embodiment will be described. FIG. 5 shows a sectional view of the semiconductor device according to the fifth embodiment.

The semiconductor device according to the present embodiment relates to a logic device using a CMOS transistor. In recent years, as logic devices become more highly integrated, low permittivity films such as a Low-k film are used as the interlayer insulating film to reduce parasitic capacitance. However, since a Low-k film has a low density in general, it tends to absorb moisture. For that reason, for example, when a temperature is applied during a molding process for packaging, a soldering process, or a reliability test, moisture will be discharged from the Low-k film within the semiconductor device. Thus, there is concern that the moisture may cause the oxidation of the contact interface thereby degrading contact yield.

In the present embodiment, as seen from FIG. 5, a first Low-k film 51 is formed on a silicon substrate (not shown), and a second Low-k film 52 and a third Low-k film 53 are successively deposited on the first Low-k film 51. A logic circuit made up of a CMOS transistor is formed on at least any one of the silicon substrate, the first Low-k film 51, the second Low-k film 52 and the third Low-k film 53.

A first contact plug 18, a second contact plug 21, and a third contact plug 22, which are respectively formed on the first Low-k film 51, the second Low-k film 52 and the third Low-k film 53, are provided with an insulating oxidizing-gas-diffusion prevention film 9 only on the side face thereof. This will prevent the oxidation of the contact interface even if moisture is discharged from the Low-k film during a thermal process, thereby enabling to avoid the degradation of contact yield.

It is noted that as shown in FIG. 5, a high-temperature interlayer insulating film 23 may be formed on the third Low-k film 53. Moreover, for example, a ferroelectric capacitor (not shown) may be formed on the high-temperature interlayer insulating film 23. Further, a Low-k film or an ordinary insulating film may be formed instead of the high-temperature interlayer insulating film 23.

Additional advantages and modifications will readily occur to those skilled in the art.

Therefore, the invention in its broader aspects is not limited to the specific details and representative embodiments shown and described herein.

Accordingly, various modifications may be made without departing from the spirit or scope of the general inventive concept as defined by the appended claims and their equivalents.

1. A semiconductor device, comprising:
a first semiconductor circuit on a semiconductor substrate;
a second semiconductor circuit above the first semiconductor circuit;
an interlayer insulating film between the first semiconductor circuit and the second semiconductor circuit; and
a contact plug that penetrates the interlayer insulating film, the contact plug comprising
a contact plug body comprising a conductor, wherein at least a side face of the contact plug body contacts the interlayer insulating film; and
a contact plug coating configured to insulate and cover at least a portion of the side face of the contact plug body in contact with the interlayer insulating film,
wherein
the first semiconductor circuit comprises a transistor comprising a gate diffusion layer and a source and drain diffusion layer;
the second semiconductor circuit comprises a ferroelectric capacitor, the ferroelectric capacitor comprising an upper electrode, a lower electrode, and a ferroelectric film, wherein the ferroelectric film is interposed between the upper electrode and the lower electrode;
the source and drain diffusion layer is electrically connected with the lower electrode of the ferroelectric capacitor by the contact plug body; and
the contact plug coating is configured to prevent an oxidizing gas from diffusing to the contact plug body, the oxidizing gas being generated from the interlayer insulating film when forming the ferroelectric film.

2. The semiconductor device of claim 1, further comprising:
a high-temperature interlayer insulating film deposited on the interlayer insulating film and comprising low pressure tetraethyl orthosilicate (LP-TEOS) or low pressure silicon nitride (LP-SiN),
wherein the ferroelectric capacitor is formed on the high-temperature interlayer insulating film.

3. The semiconductor device of claim 2, further comprising:
a hydrogen barrier film covering at least a portion of the ferroelectric capacitor, the hydrogen barrier film being configured to prevent the ferroelectric film from being deteriorated by hydrogen.

4. The semiconductor device of claim 3, wherein
the ferroelectric film comprises lead zirconate titanate (Pb[ZrₓTi₁₋ₓ]O₃ 0<x<1) or strontium bismuth tantalate (SrBi₂Ta₂O₉); and
the upper electrode and the lower electrode comprise at least one material selected from the group consisting of platinum (Pt), iridium (Ir), iridium oxide(IrO₂), strontium ruthenium oxide (SrRuO₃), ruthenium (Ru), and ruthenium oxide (RuO₂).

5. The semiconductor device of claim 3, further comprising:
a hydrogen barrier film covering at least a portion of the ferroelectric capacitor, the hydrogen barrier film being configured to prevent the ferroelectric film from being deteriorated by hydrogen.

6. The semiconductor device of claim 5, wherein
the ferroelectric film comprises lead zirconate titanate (Pb[ZrₓTi₁₋ₓ]O₃ 0<x<1) or strontium bismuth tantalate (SrBi₂Ta₂O₉); and
the upper electrode and the lower electrode comprise at least one material selected from the group consisting of platinum (Pt), iridium (Ir), iridium oxide(IrO₂), strontium ruthenium oxide (SrRuO₃), ruthenium (Ru), and ruthenium oxide (RuO₂).

7. The semiconductor device of claim 1, wherein
the ferroelectric film comprises lead zirconate titanate (Pb[ZrₓTi₁₋ₓ]O₃ 0<x<1) or strontium bismuth tantalate (SrBi₂Ta₂O₉); and
the upper electrode and the lower electrode comprise at least one kind of material selected from the group consisting of platinum (Pt), iridium (Ir), iridium oxide(IrO₂), strontium ruthenium oxide (SrRuO₃), ruthenium (Ru), and ruthenium oxide (RuO₂).

8. The semiconductor device of claim 1, wherein
the contact plug coating comprises silicon nitride (SiN) or alumina (Al₂O₃).

9. The semiconductor device of claim 1, further comprising:
a moisture barrier film covering at least a portion of the semiconductor substrate and the first semiconductor circuit, the moisture barrier film being configured to prevent intrusion of moisture into the semiconductor substrate and the first semiconductor circuit.

10. A semiconductor device, comprising:
a first semiconductor circuit on a semiconductor substrate;
a second semiconductor circuit above the first semiconductor circuit;
an interlayer insulating film between the first semiconductor circuit and the second semiconductor circuit; and
a contact plug that penetrates the interlayer insulating film, the contact plug comprising
a contact plug body comprising a conductor, wherein at least a side face of the contact plug body contacts the interlayer insulating film; and
a contact plug coating configured to insulate and cover at least a portion of the side face of the contact plug body in contact with the interlayer insulating film,
wherein
the interlayer insulating film is a Low-k film; and
the contact plug coating is configured to prevent diffusion of moisture into the contact plug body, the moisture being generated from the Low-k film when a temperature is applied to the Low-k film.

11. The semiconductor device of claim 10, further comprising:
a high-temperature interlayer insulating film deposited on the Low-k film and comprising LP-TEOS or LP-SiN; and
a ferroelectric capacitor on the high-temperature interlayer insulating film, the ferroelectric capacitor comprising an upper electrode, a lower electrode, and a ferroelectric film interposed between the upper electrode and the lower electrode.

12. A method for manufacturing a semiconductor device, comprising:
forming a first semiconductor circuit;
covering the first semiconductor circuit with an interlayer insulating film;
opening a contact hole through the interlayer insulating film;
depositing an insulating contact plug coating on a side face and a bottom face of the contact hole, the contact plug coating being configured to prevent oxidizing gas from diffusing;
removing the contact plug coating deposited on the bottom face of the contact hole;
embedding a conductor in the contact hole, thereby forming a contact plug body; and
forming a second semiconductor circuit above the interlayer insulating film,
wherein
the first semiconductor circuit comprises a transistor comprising a gate diffusion layer and a source and drain diffusion layer; and
the second semiconductor circuit comprises a ferroelectric capacitor comprising an upper electrode, a lower electrode, and a ferroelectric film, the ferroelectric film being interposed between the upper electrode and the lower electrode; and
the contact plug body is formed such that the source and drain diffusion layer of the transistor and the lower electrode of the ferroelectric capacitor are electrically connected.

13. The method of claim 12, further comprising:
after forming the contact plug body, forming a high-temperature interlayer insulating film comprising low pressure tetraethyl orthosilicate (LP-TEOS) or low pressure silicon nitride (LP-SiN) on the interlayer insulating film under a condition at about 600° C. for at least about 1 hour.

14. The method of claim 12, further comprising:
forming a hydrogen barrier film on the ferroelectric capacitor, the hydrogen barrier film being configured to prevent the ferroelectric film from being deteriorated.

15. The method of of claim 12, wherein
silicon nitride (SiN) or alumina (Al₂O₃) is used as a material in depositing the contact plug coating.

16. A method of manufacturing a semiconductor device, comprising:
forming a first semiconductor circuit;
covering the first semiconductor circuit with a barrier film, the barrier film being configured to prevent intrusion of moisture into the first semiconductor circuit;
forming an interlayer insulating film on the barrier film;
opening a contact hole penetrating the interlayer insulating film such that a surface of the barrier film is exposed;
depositing an insulating contact plug coating on a side face of the contact hole and the surface of the barrier film forming a bottom face of the contact hole, the contact plug coating being configured to prevent oxidizing gas from diffusing;
removing the contact plug coating deposited on the bottom face of the contact hole;
removing the barrier film underlying the contact plug coating that has been removed;
embedding a conductor into the contact hole, thereby forming a contact plug body; and
forming a second semiconductor circuit above the interlayer insulating film.
